(19) United States
(12) Patent Application Publication
(10) Pub. No.: US 2023/0013563 A1
(43) Pub. Date: Jan. 19, 2023

(54) JOINING TWO COMPONENTS OF A FIELD DEVICE FOR PROCESSING AND AUTOMATION TECHNOLOGY

(71) Applicant: Endress+Hauser SE+Co. KG, Maulburg (DE)

(72) Inventors: Sergey Lopatin, Lörrach (DE); Igor Getman, Lörrach (DE); Dietmar Leuthner, Weil am Rhein (DE); Pablo Ottersbach, Essen (DE)

(21) Appl. No.: 17/757,327

(22) PCT Filed: Nov. 20, 2020
(86) PCT No.: PCT/EP2020/082913

§ 371 Date: Jun. 14, 2022

(30) Foreign Application Priority Data
Dec. 16, 2019 (DE) 10 2019 134 595.2

(51) Int. Cl. G01L 9/00; B23K 35/00; B23K 35/22; B23K 35/30

(52) U.S. Cl. CPC G01L 9/006; B23K 35/007; B23K 35/226; B23K 35/3013; B23K 35/302; B23K 2103/12

(57) ABSTRACT

A field device for processing and automation technology includes a first and a second component that can each be mechanically connected at a joining surface by means of a joining point. Two metal surface layers are each applied at least to the joining surface of the first component and the joining surface of the second component. The metal of the surface layers is different from the metal of the first and/or the metal of the second component. A joining material is applied between the respective joining surfaces of the two components, wherein the joining material includes particles at least partially consisting of a metal that corresponds with the metal of the surface layers The joining of the two components occurs at a joining temperature below 300° C.

The invention relates to a device consisting of at least one first and one second component, wherein the first and the second component are components of a field device for processing and automation technology, which can each be mechanically connected at a joining surface by means of a joining point, and to a method for producing such a device.

Various field devices that are used in industrial plants are already known from the prior art. Field devices are often used in process automation, as well as in manufacturing automation.

All devices that are used in-process and that detect and/or process process-relevant information are in principle referred to as field devices. Field devices are thus used for determining and/or influencing process variables. Measuring devices, or sensors, are used for determining process variables. These are used, for example, for pressure and temperature measurement, conductivity measurement, flow measurement, pH measurement, fill-level measurement, etc., and detect the corresponding process variables of pressure, temperature, conductivity, pH value, fill-level, flow, etc. Actuators are used for influencing process variables. These are, for example, pumps or valves that can influence the flow of a liquid in a pipe or the fill level in a tank. In addition to the aforementioned measuring devices and actuators, field devices are also understood to include remote I/O's, radio adapters, or, generally, devices that are arranged at the field level. Field devices can be mounted on tanks or installed in switch cabinets or switch rooms. A variety of such field devices is produced and marketed by the Endress+Hauser group.

Generally, field devices have components which have a high sensitivity to the process variable and/or to parameters that are decisive for the determination of the process variable. Such sensitive components typically have well-defined physical properties in order to be able to determine the process variable reliably and reproducibly. It is therefore of great importance that the sensitivity of these components is not impaired during assembly or during the process. During assembly, it is particularly important to ensure that the properties of the component are not corrupted when the sensitive component is connected to a further component or several further components.

For example, vibronic measuring devices with an oscillatory unit that can be excited to mechanical oscillations are used to detect limit levels. The oscillatory unit can be designed as an oscillating fork with two rods fastened to a membrane or as a single rod with only one rod as a resonator. Typically, a piezoelectric or magnetoelectric drive, which excites the oscillatory unit to its resonant frequency, is located on the rear side of the usually thin membrane. It is crucial here that the thin and sensitive membrane is fastened in the oscillatory unit in such a way that good oscillation transmission can take place.

Another example relates to pressure measuring devices, which have a pressure-sensitive membrane in the direction of the process, which, by means of a pressure transducer, transmit a pressure acting from the process side to a pressure sensor. A pressure chamber between the membrane and a support is enclosed under the side of the membrane facing away from the process. A bore, which connects the pressure chamber to a pressure measuring chamber in which the pressure sensor is arranged, runs through the support. In addition, the pressure chamber, bore and pressure measuring chamber are filled with a pressure-transmitting liquid, which transmits to the pressure sensor the pressure acting on the membrane from the process side. Depending on the design of the pressure measuring device, the pressure measuring chamber can be arranged spatially close to or remote from the pressure chamber. In the latter case, pressure transducers are also referred to as diaphragm seals and connect the pressure chamber to the pressure sensor by means of a pressure transmission line. This design is particularly important for high-temperature processes since the pressure sensor is protected from the high process temperatures as a result of the spatial distance between pressure chamber and pressure sensor.

The membrane of a pressure measuring device is generally very thin in order to ensure the necessary pressure sensitivity. Typical membrane thicknesses are between 25 μm and 150 μm. The connection of membrane and support is therefore of particular importance in that the membrane is very susceptible to bending and stresses due to its low thickness. Known joining methods and their problems are to be discussed below on the basis of the example of the pressure transducer.

In the case of pressure transducers known from the prior art with a metallic membrane and a metallic support, membrane and support are connected to one another via a joining point. In this case, methods known from metal processing, such as soldering or welding, are used for joining the two metallic components. However, both during soldering and during welding, the choice of materials or material combinations that can be connected to one another by the respective method is limited.

A welding method used nowadays for joining metallic supports and metallic membranes is laser beam welding. This makes it possible to produce high-quality, pressure-resistant joining points between supports made of stainless steel and membranes made of stainless steel or of nickel alloys, such as alloys known under the brand name Hastelloy. Welding seams arising during laser beam welding, however, have a comparatively high surface roughness. Pressure transducers with rough surfaces generally cannot be used in applications with high requirements for hygiene and cleanability of the transducer. Moreover, welding seams increase the risk of corrosion, which in the long run can even lead to failure of the pressure transducer in the worst case.

This problem can be remedied in a manner known from the prior art in that the membrane is soldered flat to the support. For this purpose, a solder suitable for joining the materials of the membrane and support, generally a special alloy on the basis of silver, copper, or nickel, is introduced as a solder layer between the joining surfaces of the support and the membrane and is fused under vacuum or in a protective gas atmosphere. This method can produce pressure transducers having very smooth surfaces that are in contact with the medium, thus fulfilling high hygiene requirements.

However, soldering can only be used if the support and the membrane have identical or at least similar coefficients of thermal expansion. The reason for this is that during soldering of components with different coefficients of thermal expansion, thermomechanical stresses arise due to the required high soldering temperature and lead to permanent stresses of the membrane. The soldering temperature depends on the choice of solder and can easily be in the range of approximately 700° C. to 1100° C. for today's common solders. At these high temperatures, even comparatively small differences of the coefficients of thermal expansion can lead to deformations and to permanent stresses of the membrane, which strongly impair the pressure transmission properties thereof.

Moreover, during soldering, there is the risk of liquid solder penetrating into the pressure chamber during the soldering process. Penetrating solder leads to uncontrolled reduction of the internal volume of the pressure chamber, to an undetermined change in the membrane flexibility, and may possibly lead to limitations or impairments of the deflections which the membrane experiences as a function of a pressure acting thereon. A further disadvantage of flat soldering is that gas bubbles in the liquid solder can form between the joining surfaces of the support and the membrane due to gas inclusions. Gas bubbles can cause cavities to remain within the joining point after cooling, which cavities impair the quality of the joining point.

For some metals, soldering is also not applicable as a joining method since metals such as duplex and super duplex steel lose their corrosion resistance at temperatures above 280-300° C. Components of these metals can alternatively be glued. However, the glued joining point is not very robust with regard to rapidly changing process conditions, such as a temperature shock.

Metallic or intermetallic joining points have, for example, become known from the prior art from DE 102016112198 A1 and DE 102016112200 A1. Here, metallic joining means are applied to the respective joining surface of membrane and support, and the membrane and the support are subsequently joined at their joining surfaces by thermocompression bonding or by reactive bonding. In both specifications, joining temperatures below 300° C. are disclosed, provided that at least one of the joining means applied to the membrane or support contains tin. The comparatively low joining temperature reduces stresses in the membrane and the joining point. However, especially intermetallic joining points with tin are generally brittle, since tin partially oxidizes in air at these joining temperatures or during storage, thereby preventing homogeneous layer formation.

It is an object of the invention to specify a pressure transducer that overcomes the aforementioned problems, as well as a method for the production thereof.

This object is achieved by a device according to the invention as per claim 1 and a method according to the invention for producing a device as per claim 14.

The device according to the invention consists of at least one first and one second component, wherein the first and the second component are components of a field device for processing and automation technology, which are each mechanically connected to one another at a joining surface by means of a joining point, obtainable by a method comprising the following steps:
coating in each case at least the joining surface of the first and of the second component with a metallic surface layer, wherein the metal of the surface layers is different from the metal of the first and/or the metal of the second component,
applying a joining material between the respective joining surfaces of the two components, wherein the joining material comprises at least particles at least partially consisting of a metal, wherein the metal of the joining material corresponds with the metal of the surface layers, and
joining the first and second components at their respective joining surface by heating at a joining temperature below 300° C.

The great advantage of the invention is that the joining point between the two components is achieved at comparatively low joining temperatures. Thus, stresses in the two components and at the joining point are avoided or at least greatly reduced. This applies especially when the two components consist of materials with different coefficients of thermal expansion. The physical properties of the components defined prior to the joining remain after the joining of the two components. In contrast to a welding process, a joining point that does not have high surface roughness but a smooth surface structure is obtained in the case of the pressure transducer according to the invention. As a result, the pressure transducer according to the invention is also suitable for hygienic applications.

By using the same metal for the joining material and the surface layers, the metal atoms can diffuse both between the individual particles and between the particles and the surface layers.

This achieves uniform distribution of the metal atoms and thus a homogeneous joining point and good adhesion. Delamination of the joining material is thus ruled out. The joining process can be accelerated by prestressing the two components at 1-50 MPa. It is possible for the surface layer to be applied only to the joining surface of the first and the second component in each case, or also for all of the second component, for example, to be provided with a surface layer.

In one possible embodiment, the device relates to a pressure transducer, wherein the first component is a metallic support and the second component is a metallic membrane arranged on the metallic support so as to enclose a pressure chamber. Here, the joining at low joining temperatures is particularly advantageous since the membrane is very thin and thus susceptible to stresses.

In one embodiment, the particles have silver or copper or gold as metal. Gold is highly corrosion-resistant. Silver oxides and silver salts are reduced to metallic silver at temperatures above 200-250° C. Should the joining point made of silver start oxidizing at the surface over time, the resulting silver oxide would be restored to metallic silver in a process that is accompanied by temperatures above 200° C. Thus, a form of self-cleaning of the silver joining point is achieved at corresponding temperatures. As already described, the surface layer also has silver, copper or gold in a manner corresponding to the particles. The surface layer can also extend over the entire component. A thin gold layer, for example from a component which contacts a medium, protects the component against corrosion and forms a very effective diffusion barrier with respect to hydrogen. Hydrogen, which, for example, diffuses into a pressure transducer or more precisely into the liquid in the pressure transducer, changes the pressure transmission properties of the pressure transducer and can even lead to failure of the pressure transducer in the worst case. A surface layer of silver also effectively protects against penetration of hydrogen into the pressure transducer.

In a further embodiment, the particles comprise especially silver nitrate, silver acetate, silver carbonate or silver oxide. As already described, temperatures above 200° C. lead to a reduction of silver, starting from silver salts and silver oxide. The use of particles with silver salts or silver oxide therefore leads to the release of silver during the joining.

A further embodiment provides that the particles have a silver, copper, or gold alloy.

The joining material advantageously comprises at least a liquid and/or a solvent and/or an additive agent in addition to the particles at least partially consisting of metal. The three additives mentioned serve for easier application of the joining material to the respective joining surfaces of the first and the second component. By means of appropriate additives, the joining material can, for example, obtain a pasty structure and thus be spread onto the two joining surfaces without the joining material running from the two joining surfaces onto other surfaces of the two components. When the joining material is heated to the joining temperature, the additives are either evaporated or decomposed. Ideally, the volume fraction of the at least one additive in the joining material is in this case so low that the desorption or decomposition of the additive does not impair the joining process or the quality of the joining point.

In a preferred embodiment, the diameter of the particles at least partially consisting of metal is less than 1 μm. Metallic particles with such a diameter have a high surface energy, which is why the particles are sintered even at comparatively low temperatures, such as the joining temperature. The diffusion of metal atoms between the particles thus produces a homogeneous joining point.

In a further embodiment, the first component can be manufactured from stainless steel, especially, duplex steel and/or super duplex steel, and/or unalloyed steel and/or Monel and/or a copper alloy, and the second component can be manufactured from stainless steel, especially, duplex steel and/or super duplex steel, and/or Hastelloy and/or tantalum and/or Monel and/or titanium and/or zirconium and/or a copper alloys and/or a silver alloys and/or a gold alloys.

Advantageously, the metallic surface layer is applied to the membrane and the support by means of galvanic processes or sputtering. Depending on the metal of the first and of the second component, it is often possible to use only one of the two methods for applying the metallic surface layer. For example, tantalum and zirconium cannot be galvanically coated in aqueous solutions but must be sputtered. What is decisive for the choice of the method is that the surface layer adheres well to the respective component and does not detach.

Preferably, the metallic surface layer has a thickness of 2 to 30 μm. With this thickness of the metallic surface layer, an optimal joining point is obtained.

In one possible embodiment, an additional adhesive layer is applied between the first component and the surface layer and between the second component and the surface layer and respectively connects the surface layer to the first and the second component. These adhesive layers are necessary since not all metals of the two components adhere well directly to the metal of the surface layer. The adhesive layer thus serves for the adhesion and connection between the two components and their respective surface layer.

A further embodiment provides that especially adhesive gold or copper or chromium can be used as an adhesive layer.

In a preferred embodiment, the joining temperature is especially in the range of 250° C. to 280° C.

The object underlying the present invention is furthermore achieved by a method for producing a device consisting of at least one first and one second component, wherein the first and the second component are components of a field device for processing and automation technology, which can each be mechanically connected at a joining surface by means of a joining point, wherein the method comprises the following steps:
coating in each case at least the joining surface of the first and of the second component with a metallic surface layer, wherein the metal of the surface layers is different from the metal of the first and/or the metal of the second component,
applying a joining material between the respective joining surfaces of the two components, wherein the joining material comprises at least particles at least partially consisting of a metal, wherein the metal of the joining material corresponds with the metal of the surface layers, and
joining the first and second components at their respective joining surface by heating at a joining temperature below 300° C.

By using particles at least partially consisting of metal, a homogeneous joining point is obtained even at comparatively low joining temperatures, since the particles are sintered even at low temperatures due to their high surface energy. Due to the low joining temperature, different metals of the first and the second component can also be joined to one another without stresses occurring in the components and/or the joining point. In addition, a smooth joining point is obtained, which can also be used for hygienic applications. The surface layer serves to connect the joining material to the first and to the second component and thus ensures that no delamination occurs.

Advantageously, the method provides an additional step,
coating the joining surface of the first and the second component in each case with an adhesive layer, which is respectively arranged between the surface layer and the first and the second component.

The metal of the joining material and of the surface layer does not readily adhere to the metal of the first and of the second component in all cases. The adhesive layer therefore serves to connect the surface layer to the first and the second component.

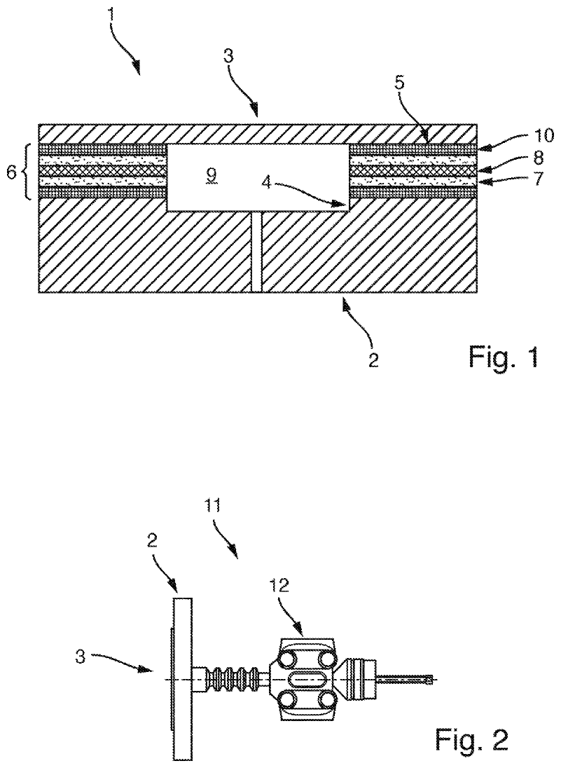

The solution according to the invention is explained in greater detail with reference to the following FIGS. 1-2. The following is shown:

FIG. 1 a schematic representation of a pressure measuring device.

FIG. 2 a schematic representation of a pressure transducer according to the invention.

The present invention is applicable to a plurality of different field devices. Without limiting generality, however, the following description relates to a pressure measuring device, as schematically illustrated in FIG. 1, for the sake of simplicity. Corresponding pressure measuring devices are produced and marketed by the applicant under the names “Cerabar,” “Ceraphant,” and “Deltabar,” for example. The considerations can be applied analogously to other field devices which have at least one component with a high sensitivity to the process variable and/or to parameters that are decisive for the determination of the process variable.

FIG. 1 shows a schematic representation of a corresponding pressure measuring device 11. In this case, the membrane 3 faces the process and adjoins the support 2. The pressure sensor 12 is located at a certain distance from the membrane 3 and the support 2. The pressure acting on the membrane 3 is transmitted to the pressure sensor 12 by means of a liquid (not shown).

FIG. 2 shows a possible embodiment of the device according to the invention on the basis of a pressure transducer 1. The membrane 3 and the support 2 are arranged opposite one another, with joining surfaces 4, 5 facing one another, at which the membrane 3 and support 2 can be connected. A pressure chamber 9 is arranged between the membrane 3 and the support 2 and is adjoined by a bore extending through the support 2. The support 2 can be manufactured from stainless steel, especially, duplex steel and/or super duplex steel, and/or unalloyed steel and/or Monel and/or a copper alloy, and the membrane 3 can be manufactured from stainless steel, especially, duplex steel and/or super duplex steel, and/or Hastelloy and/or tantalum and/or Monel and/or titanium and/or zirconium and/or a copper alloys and/or a silver alloys and/or a gold alloys.

An adhesive layer 10 is applied to the respective joining surface of membrane and support 4, 5. The adhesive layer 10 can consist of adhesive gold, copper, chromium or further substances. In each case, a surface layer 7 is applied at least to the joining surface of the membrane 5 and the joining surface of the support 4, for example by means of a galvanic process or by means of sputtering, wherein the metal of the surface layers 7 is different from the metal of the support 2 and/or the metal of the membrane 3. One possible combination would be the coating of membrane 3 and support 2, both of which are made of stainless steel, with a layer of silver. Advantageously, the metallic surface layer 7 has a thickness of 2 to 30 μm.

A joining material 8 is applied between the respective surface layers 7 in the region of the joining surface of membrane and support 4, 5 and comprises at least particles at least partially consisting of a metal. The metal of the joining material 8 corresponds with the metal of the surface layers 7. The particles have, for example, gold, copper, or silver, as well as alloys of these metals, or also silver nitrate, silver acetate, silver carbonate, or silver oxide. In addition to the particles, the joining material 8 also consists of at least a liquid and/or a solvent and/or an additive agent. The diameter of the particles is less than 1 μm, with other possibilities not being ruled out. The joining takes place at joining temperatures below 300° C., for example at 250-280° C.

A device 1 of this kind, such as a pressure transducer, is produced by means of a method according to the invention by first coating the first and second components 2, 3 on at least their respective joining surface 4, 5 with a surface layer 7. The surface layer 7 has a metal which is different from the metal of the first and second components 2, 3. Subsequently, the joining material 8 is applied to the respective joining surfaces of the two components 4, 5. The joining material 8 comprises at least particles at least partially consisting of metal, wherein the metal of the joining material 8 corresponds with the metal of the surface layers 7 so that good adhesion between the joining material 8 and the surface layer 7 is obtained. In a further step, the two components 2, 3 are joined at their respective joining surfaces 4, 5 at a joining temperature of below 300° C. Optionally, before the application of the surface layer 7, the joining surfaces of the first and the second component 4, 5 can first be coated with an adhesive layer 10, which connects the surface layer 7 to the first and the second component 2, 3.

### LIST OF REFERENCE SIGNS

1 Device or pressure transducer

2 First component or support

3 Second component or membrane

4 Joining surface of the first component or of the support

5 Joining surface of the second component or of the membrane

6 Joining point

7 Surface layer

8 Joining material

9 Pressure chamber

10 Adhesive layer

11 Pressure measuring device

12 Pressure sensor

1-15. (canceled)

16. A field device for process automation, comprising:
a first metal component and a second metal component, wherein the first component and the second component are mechanically connected to one another at a joining surface via a joining point, wherein the connecting of the first component with the second component includes:
coating a joining surface of the first component and a joining surface of the second component with a metallic surface layer, wherein the metal of the surface layers is different from the metal of the first and/or the metal of the second component;
applying a joining material between the respective joining surfaces of the two components, wherein the joining material includes particles at least partially consisting of a metal, wherein the metal of the joining material corresponds with the metal of the surface layers; and
joining the first and second components at their respective joining surface by heating at a joining temperature below 300° C.

17. The field device according to claim 16,
wherein the field device relates to a pressure transducer, wherein the first component is a metallic support and the second component is a metallic membrane arranged on the metallic support so as to enclose a pressure chamber.

18. The field device according to claim 16,
wherein the particles have silver or copper or gold as metal.

19. The field device according to claim 16,
wherein the particles comprise silver nitrate, silver acetate, silver carbonate, or silver oxide.

20. The field device according to claim 16,
wherein the particles have a silver, copper, or gold alloy.

21. The field device according to claim 16,
wherein the joining material includes at least a liquid and/or a solvent and/or an additive agent in addition to the particles at least partially consisting of metal.

22. The field device according to at least claim 16,
wherein the diameter of the particles at least partially consisting of metal is less than 1 μm.

23. The field device according to claim 16,
wherein the first component is manufactured from stainless steel, duplex steel and/or super duplex steel, and/or unalloyed steel and/or Monel and/or a copper alloy, and
wherein the second component is manufactured from stainless steel, duplex steel and/or super duplex steel, and/or Hastelloy and/or tantalum and/or Monel and/or titanium and/or zirconium and/or a copper alloys and/or a silver alloys and/or a gold alloys.

24. The field device according to claim 16,
wherein the metallic surface layer is applied to the two components by galvanic processes or sputtering.

25. The field device according to claim 24,
wherein the metallic surface layer has a thickness of 2 to 30 μm.

26. The field device according to claim 16,
wherein an additional adhesive layer is applied between the first component and its surface layer and between the second component and its surface layer and respectively connects the surface layer to the first and the second component.

27. The field device according to claim 26,
wherein adhesive gold or copper or chromium is used as the adhesive layer.

28. The field device according to claim 16,
wherein the joining temperature is in the range of 250° C. to 280° C.

29. A method for producing a device consisting of at least one first and one second component, wherein the first and second components are components of a field device for processing and automation technology, which can each be mechanically connected at a joining surface via a joining point, the method comprising:
coating in each case at least the joining surface of the first and of the second component with a metallic surface layer, wherein the metal of the surface layers is different from the metal of the first and/or the metal of the second component;
applying a joining material between the respective joining surfaces of the two components, wherein the joining material includes at least particles at least partially consisting of a metal, wherein the metal of the joining material corresponds with the metal of the surface layers, and
joining the first and second components at their respective joining surface by heating at a joining temperature below 300° C.

30. The method according to claim 29, further comprising:
coating the joining surface of the first and second components in each case with an adhesive layer that is respectively arranged between the surface layer and the first and second components.
